(19) United States
(12) Patent Application Publication
(10) Pub. No.: US 2025/0221014 A1
(43) Pub. Date: Jul. 3, 2025

(54) BIPOLAR TRANSISTOR REVERSE RECOVERY

(71) Applicant: Texas Instruments Incorporated, Dallas, TX (US)

(72) Inventor: Aravind Appaswamy, Plano, TX (US)

(21) Appl. No.: 18/400,553

(22) Filed: Dec. 29, 2023

(51) Int. Cl. H01L 27/082; H01L 21/8228; H01L 29/66; H01L 29/735

(52) U.S. Cl. CPC H10D 84/645; H10D 10/061; H10D 10/60; H10D 84/0119; H10D 84/038

(57) ABSTRACT

An electronic device includes an NPN bipolar transistor in an isolation tank region of an n-type semiconductor layer and having a p-type base region, an n-type emitter region, and an n-type collector region and a PNP bipolar transistor in the isolation tank region of the semiconductor layer and having an n-type base formed by a portion of the n-type semiconductor layer, a p-type emitter formed by a portion of the p-type base region of the NPN bipolar transistor, and a p-type collector formed by a p-type second collector region in the isolation tank region of the semiconductor layer and spaced apart from the p-type base region and from the n-type collector region of the NPN bipolar transistor.

### BACKGROUND

Bipolar transistors can be isolated in an integrated circuit by junction implants or deep trench isolation structures. One characteristic of such transistors is reverse recovery time, which may limit the frequency response of the transistor.

### SUMMARY

In one aspect, an electronic device includes a semiconductor layer, a base region, an emitter region, and first and second collector regions. The semiconductor layer extends over a substrate, having a top surface and an isolation tank region extending from the top surface into the semiconductor layer. The base region has a first conductivity type and extends from the top surface into the isolation tank region, and the semiconductor layer has an opposite second conductivity type. The emitter region has the second conductivity type and extends from the top surface into the base region. The first collector region has the second conductivity type and extends from the top surface into the isolation tank region and is spaced apart from the base region. The second collector region has the first conductivity type and extends from the top surface into the isolation tank region spaced apart from the base region and from the collector region.

In another aspect, an integrated circuit includes an epitaxial layer over a semiconductor substrate, an isolation structure surrounding an isolation tank region and including a portion of the epitaxial layer, a base well having a first conductivity type and extending into the isolation tank region, the epitaxial layer having an opposite second conductivity type, and a transistor terminal having the second conductivity type and extending into the base well. The integrated circuit includes a first well having the second conductivity type and extending into the isolation tank region and spaced apart from the base well, and a second well having the first conductivity type and extending into the isolation tank region and spaced apart from the base well, where the transistor terminal, the base well, the isolation tank region, and the first well form a first bipolar transistor having a first polarity type, and the base well, the isolation tank region, and the second well form a second bipolar transistor having a second polarity type.

In another aspect, a method of fabricating an electronic device includes forming a base region having a first conductivity type in an isolation tank region of a semiconductor layer over a substrate that supports the semiconductor layer, the semiconductor layer having a second conductivity type, forming an emitter region having the second conductivity type in the base region, forming a first collector region having the second conductivity type in the isolation tank region and spaced apart from the base region, and forming a second collector region having the first conductivity type in the isolation tank region and spaced apart from the base region and from the collector region.

### BRIEF DESCRIPTION OF THE DRAWINGS

FIG. 1 is a partial top plan view of an electronic device with a bipolar transistor in an isolation tank.

FIG. 1A is a partial side elevation view of the electronic device taken along line 1A-1A of FIG. 1.

FIG. 1B is a top perspective view of the electronic device of FIGS. 1 and 1A.

FIG. 2 is a flow diagram of a method of fabricating an electronic device.

FIGS. 3-19 are partial side elevation views of the electronic device of FIGS. 1-B undergoing fabrication processing according to the method of FIG. 2.

FIG. 20 is a partial top plan view of another electronic device with a bipolar transistor in an isolation tank.

FIG. 21 is a partial top plan view of yet another electronic device with a bipolar transistor in an isolation tank.

FIGS. 22 and 23 are graphs showing comparative reverse recovery performance.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. Described examples include doped regions of various semiconductor structures which may be characterized as p-doped and/or n-doped regions or portions and include regions that have majority carrier dopants of a particular type, such as n-type dopants or p-type dopants, and such regions or portions should be interpreted as having the conductivity type as n-type or p-type, respectively. One or more structures, features, aspects, components, etc., may be referred to herein as first, second, third, etc., such as first and second terminals, first, second, and third, wells, etc., for ease of description in connection with a particular drawing, where such are not to be construed as limiting with respect to the claims. Various disclosed structures and methods of the present disclosure may be beneficially applied to manufacturing an electronic device such as an integrated circuit. While such examples may be expected to provide various improvements, no particular result is a requirement of the present disclosure unless explicitly recited in a particular claim.

The disclosure recognizes that reverse recovery time of some bipolar transistors is determined in part by the time needed to remove holes (for the example of an NPN transistor) that are injected into the collector when the transistor is in a reverse-bias state, e.g. negative base-emitter bias. Various examples may improve the performance of such transistors by providing a parasitic PNP transistor that provides a conductive path for the holes to the device substrate, thereby reducing the reverse recovery time. While such examples may be expected to improve device performance parameters such as maximum operating frequency, no particular result is a requirement unless explicitly recited in a particular claim.

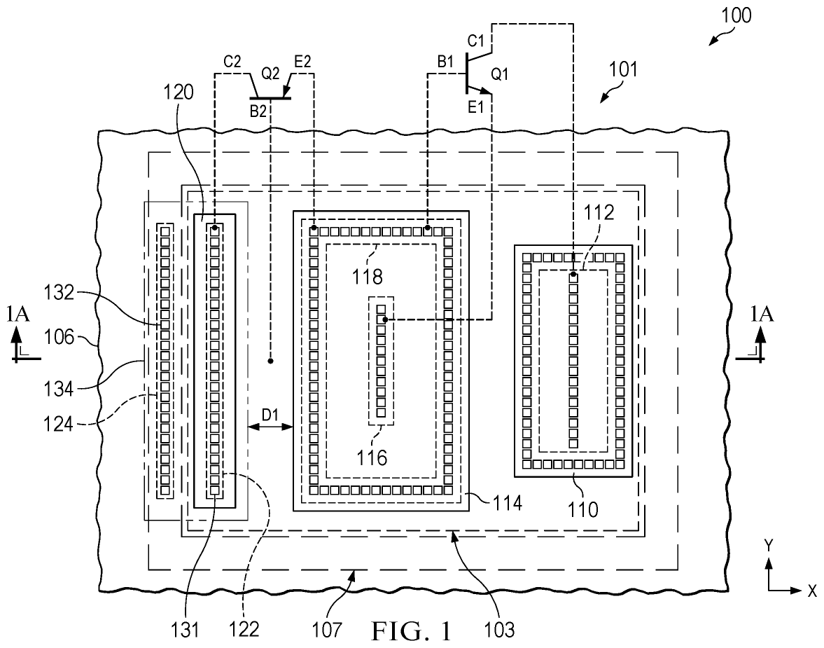

FIGS. 1, 1A and 1B show an electronic device 100 with a semiconductor die 101 that includes a semiconductor substrate 102 (FIG. 1A) that is or includes silicon or other suitable semiconductor material and has a first conductivity type (e.g., includes majority carrier dopants of a first type, such as p-type, labeled “SUBSTRATE” in FIG. 1A). The electronic device 100 includes a bipolar NPN transistor formed in an isolation tank 103 illustrated in FIG. 1A. The electronic device 100 is shown in an example three-dimensional space with a first direction X, a perpendicular (orthogonal) second direction Y (FIGS. 1 and 1B), and a third direction Z (FIGS. 1A and 1B) that is perpendicular (orthogonal) to the respective first and second directions X and Y.

A semiconductor layer 104 (e.g., epitaxial silicon, which may be referred to as second semiconductor layer 104 or epitaxial layer 104) extends above the semiconductor substrate 102 as shown in FIG. 1A and has the first conductivity type (e.g., includes majority carrier dopants of the first type, such as p-type, labeled “P EPI” in FIG. 1A). A buried layer 105 having an opposite second conductivity type (e.g., includes majority carrier dopants of a second type, such as n-type, labeled “NBL” in FIG. 1A) extends from the epitaxial semiconductor layer 104. In the examples described hereinafter, the first conductivity type is p-type and the second conductivity type is n-type. In other implementations not explicitly shown, similar benefits and structures can be fabricated by reversing the conductivity types of various structures, for example, wherein the first conductivity type can be n-type and the second conductivity type can be p-type.

As shown in FIG. 1A, a semiconductor layer 106 (e.g., epitaxial silicon, which may be referred to as first semiconductor layer 106 or epitaxial layer 106) extends over the substrate 102 from the epitaxial layer 104 and from the buried layer 105. The semiconductor layer 106 has the second conductivity type (e.g., includes n-type majority carriers) and is labeled “N EPI” in FIG. 1A. The semiconductor layer 106 has a top surface extending in a plane of the respective first and second directions X and Y and includes the isolation tank 103 that extends from the top surface into the semiconductor layer 106 to the buried layer 105. An upper portion of the buried layer 105 extends into a lower portion of the semiconductor layer 106 in the illustrated example, for example, by diffusion of n-type dopants originally implanted in the epitaxial layer 104 into the lower portion of the semiconductor layer 106.

As further shown in FIGS. 1 and 1A, a deep trench isolation structure 107 extends from the top surface through the semiconductor layer 106 and into the substrate 102. The substrate 102 underlies the deep trench isolation structure 107 and the deep trench isolation structure 107 laterally surrounds the isolation tank 103 of the semiconductor layer 106. The buried layer 105 extends between the semiconductor layer 106 and the substrate 102 and is laterally bounded by the deep trench isolation structure 107 that laterally surrounds the isolation tank 103, as shown in FIGS. 1 and 1A. In the illustrated example, the buried layer 105 does not extend laterally outward of the deep trench isolation structure 107. In another example, portions of the buried layer 105 extend laterally outward beyond portions of the deep trench isolation structure 107 (e.g., along the first direction X in the view of FIG. 1A). As shown in FIG. 1A, deep trench isolation structure 107 in one example includes a trench with a sidewall liner 108 (e.g., an oxide or other insulator), as well as doped polysilicon 109 on the sidewall liner 108 that extends from the top surface of the epitaxial semiconductor layer 106 to the substrate 102.

As shown in FIGS. 1 and 1A, the electronic device 100 includes first and second bipolar transistors Q1 and Q2 within the isolation tank 103. In the illustrated example the transistor Q1 is an NPN transistor, and includes an n-type collector C1 realized by a first collector region which may also be referred to as C1. The first collector region C1 includes an n-type well, or region, 110 (e.g., labeled “N-WELL” in FIG. 1A and sometimes referred to as deep well 110 or n-well 110) with majority carriers of the second type having a dopant concentration that is greater than that of the n-type epitaxial layer 106. The first collector region C1 also includes a more heavily doped n-type region 112 (sometimes referred to as collector contact 112) that extends to the top surface of the epitaxial semiconductor layer 106 within the deep implanted region 110. The shallow n-type implanted region 112 in one example has an n-type dopant concentration that is greater than that of the deep implanted region 110, e.g., is degenerately doped, and is labeled “N+” in FIG. 1A. The n-well 110 and the collector contact 112 may both be formed by ion implantation and diffusion. The collector C1 is further realized by the semiconductor layer 106, which provides a conductive path between the n-well 110 and a p-type base B1.

The base B1 is realized by a p-type base region 114 (e.g., labeled “P” in FIG. 1A) and a more heavily doped p-type base contact region 118 (labeled “P+” in FIG. 1A, sometimes referred to as implanted region 118 or base contact 118) within the base region 114, both of which may be formed by ion implantation. The transistor Q1 further includes an n-type emitter region (E1) realized by a heavily doped region 116 having majority carriers of the second conductivity type (e.g., n-type, labeled “N+” and FIG. 1A). The doped region 116, sometimes referred to as implanted region 116, emitter region 116, or emitter contact region 116, may be formed by ion implantation and diffusion. In the illustrated example, the p-type base contact region 118 laterally encircles the n-type emitter region 116 in the p-type base region 114. In one example, the n-type emitter region 116 has an n-type dopant concentration that is approximately the same as that of the n-type implanted region 112 of the collector C1, and the implanted regions 112 and 116 extend to approximately the same depth along the third direction Z in one example.

The second transistor Q2 in this example is a parasitic PNP bipolar transistor Q2 in the isolation tank 103 of the semiconductor layer 106 with an n-type base B2 realized by the n-type semiconductor layer 106, or the collector of the transistor Q1. The second transistor Q2 has a p-type emitter E2 realized by the p-type base B1 (including base region 114 and base contact region 118) of the NPN bipolar transistor Q1.

The second transistor Q2 also has a p-type collector C2, sometimes referred to as a second collector region. The p-type collector C2 is realized by a p-type second collector region that includes a p-type well region 120 (e.g., labeled “P” in FIG. 1A, sometimes referred to as implanted region 120) with majority carriers of the first type, as well as a more heavily doped shallow p-type implanted region 122 that extends to the top surface of the epitaxial semiconductor layer 106 within the well region 120. The p-type regions 120, 122 in this example extend from the top side of a portion of the epitaxial semiconductor layer 106 in the isolation tank 103 and is laterally spaced apart from the p-type base B1 and from the n-type collector C1 (including the deep implanted region 110 and collector contact 112) of the NPN bipolar transistor Q1 (e.g., along the first direction X in the view of FIG. 1A). The epitaxial semiconductor layer 106 extends to top surface between the p-type implanted region 120 and the base region 114 of the NPN transistor Q1.

The shallow n-type implanted region 122 in one example has a p-type dopant concentration that is greater than that of the implanted region 120 and is labeled “P+” in FIG. 1A. In one example, the p-type base region 114 and the p-well 120 extend to approximately the same depth in the epitaxial semiconductor layer 106 along the third direction Z and have the same or similar p-type dopant concentrations. In this or another example, the more heavily doped (e.g., P+) p-type implanted regions 118 and 122 extend to approximately the same depth as one another along the third direction Z in the epitaxial semiconductor layer 106 and have the same or similar p-type dopant concentrations as one another. In one example, p-type implanted regions 124 provide ohmic contacts to the doped polysilicon 109 of the deep trench isolation structure 107 as shown in FIG. 1A. The implanted regions 124 may also be referred to as deep-trench contacts 124 or DT contacts 124. In some examples the doped polysilicon 119 is p-type and directly contacts the substrate 102, thus providing a conductive path from the DT contacts 124 and the substrate 102.

As further shown in FIG. 1, the lateral sides of the p-type base region 114 and the p-well 120 are laterally spaced apart from one another along the first direction X by a distance D1, for example, which can be tailored according to a breakdown voltage rating of a particular design of the NPN first transmitter Q1. The second (PNP) transistor Q2 in this example is a parasitic transistor which serves to help fast reverse recovery of the NPN first transistor Q1. The inclusion of the p-type regions 120, 122 facilitates extraction of hole carriers from the n-type isolation tank 103 following reverse biasing of the transistor Q1. The added p-type implanted region or regions 120, 122 provide a hole extraction path to a low potential node, such as the substrate 102 to facilitate fast reverse recovery of the transistor Q1. In particular, the added p-type regions (e.g., second collector region) 120, 122 can be connected to any low potential node to facilitate enhanced reverse recovery.

In the illustrated example, the electronic device 100 includes a metallization structure 130 as shown in FIG. 1A. The metallization structure 130 includes first and second vertical metal interconnects 131 and 132 (e.g., vias or contacts including tungsten or other suitable conductive metal) in a pre-metal dielectric (PMD) layer 133, and a metal trace feature 134 in a first interlevel or interlayer dielectric (ILD) layer 135. The metal trace feature 134 and other metal trace features may include aluminum or copper traces formed by any suitable process. The metallization structure 130 in one example includes a third level with conductive metal terminals 136, such as bond pads, die pads, etc., they can provide terminal connections to interconnect the semiconductor die 101 and the transistor Q1 thereof, for example, by bond wire connections, or soldering of one or more terminals 136 to a substrate or lead frame (not shown) during packaging of the electronic device 100. The contacts (e.g., interconnects 131 and 132) of the PMD level extend downward along the third direction Z to provide electrical connection to respective portions of the top side of the epitaxial semiconductor layer 106, and the connections may include conductive metal silicide (not shown).

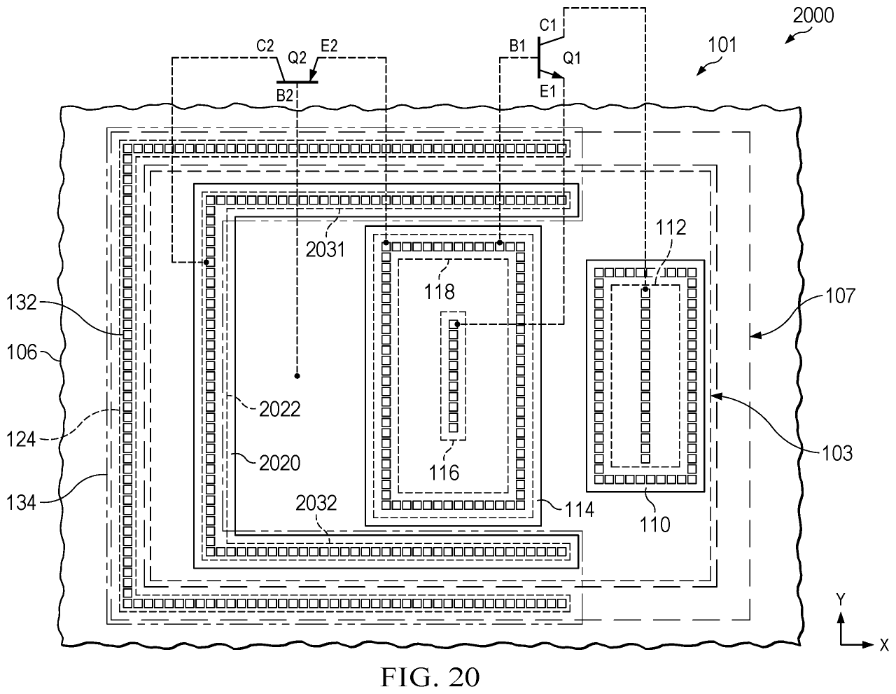

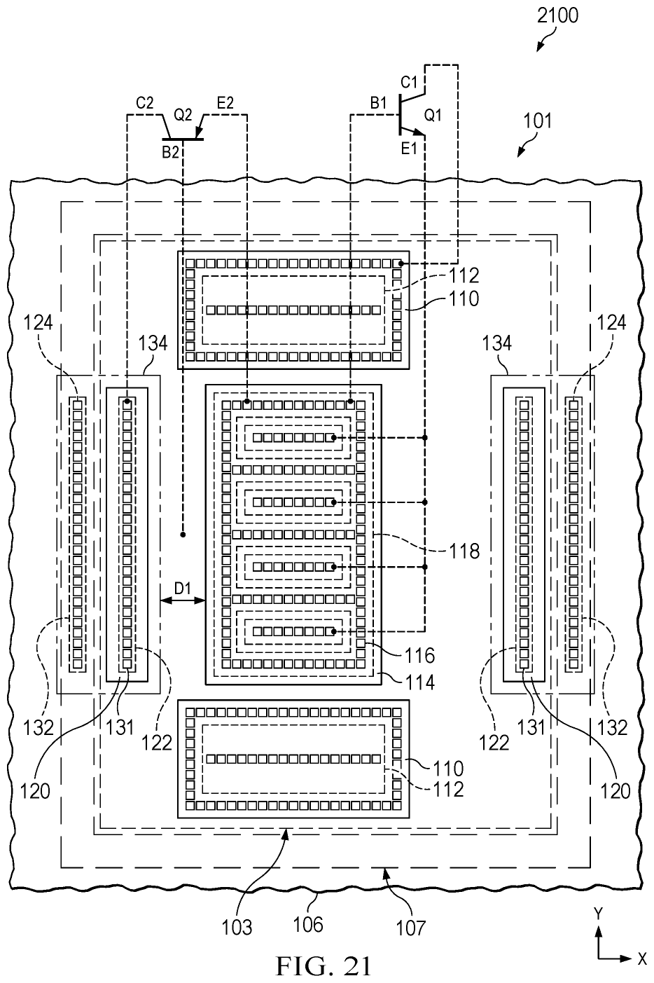

The first metal interconnect 131 in the illustrated example provides an electrical connection to the heavily doped p-type implanted region 122 within the implanted region 120 (e.g., the second collector region C2 of the parasitic PNP bipolar second transistor Q2). The first metal interconnect 131 extends to and contacts a portion of the conductive metal trace feature 134 of the first ILD level of the metallization structure 130. The second metal interconnect 132 of the PMD level extends from another portion of the metal trace feature 134 downward along the third direction Z to the conductive doped polysilicon 109 of the deep trench isolation structure 107 (e.g., including any heavily doped (e.g., P+) region 124 thereof). This example structure provides a conductive path from the p-type regions 120, 122 to facilitate hole extraction therefrom through the metallization structure 131, 134, 132 and through the doped polysilicon 109 to the substrate 102. In another implementation, the p-type regions 120, 122 can be electrically connected (e.g., by associated features of the metallization structure 130) to another low potential node. The described example and other implementations (e.g., FIGS. 20 and 21 below) provide a solution to slow reverse recovery operation of the bipolar transistor in isolation tank 103 without forming Schottky diodes or other reverse recovery components while realizing the space saving benefits of deep trench-based bipolar transistor isolation.

The interconnection of the p-type regions C2 (120, 122) to a low potential node in the electronic device 100 advantageously provides a low impedance path to extract hole carriers from the n-type epitaxial silicon of the semiconductor layer 106 in the isolation tank 103, and thereby enhance snapback current capacity of the electronic device 100 to provide fast reverse recovery of the NPN transistor Q1. In other implementations (e.g., FIGS. 20 and 21 below), different structural relationships and arrangements of the elements of the NPN bipolar transistor Q1 and the added second collector region C2 can be provided within the isolation tank 103 bounded by an isolation structure (e.g., deep trench isolation structure 107) in order to facilitate one or more low impedance conduction paths or other conductive connection from an epitaxial semiconductor portion (e.g., n-type epitaxial silicon of the semiconductor layer 106 within the isolation tank 103) to the substrate 102 or other low potential node (e.g., through the deep trench isolation structure 107 or other conductive connection) in operation of the electronic device 100 to provide enhanced reverse recovery performance in operation of the transistor Q1.

Referring also to FIG. 1B, the electronic device 100 in one example is an integrated circuit having the above-described semiconductor die 101 packaged with electrical connections formed between conductive terminals (e.g., terminals 136) and one or more conductive features of a starting lead frame and/or a package substrate (not shown). The package interconnections can be made by any suitable structures and techniques, including without limitation wire bonding, flip chip soldering of the terminals 136 of the semiconductor die 101, etc. The example electronic device 100 in FIG. 1B has opposite bottom and top sides 141 and 142 spaced apart from one another along the third direction Z, respectively, as well as laterally opposite third and fourth sides 143 and 144, and laterally opposite ends 145 and 146. The semiconductor die 101 has one or more terminals electrically connected to respective ones of conductive metal leads 147, for example, conductive portions of a starting lead frame and/or package substrate (not shown). In this example portions of the leads 147 and the semiconductor die 101 are at least partially enclosed by a molded or ceramic package structure 148 that defines the sides 141-146. The leads 147 can be soldered or otherwise electrically connected to a host system (e.g., a printed circuit board or PCB, not shown) by suitable solder connections, installation in a socket, etc.

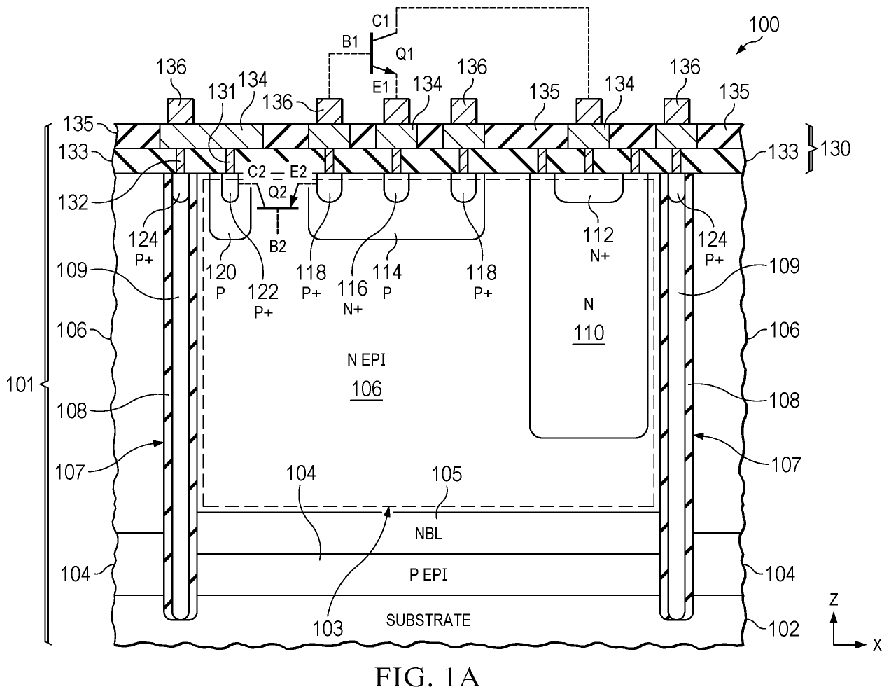

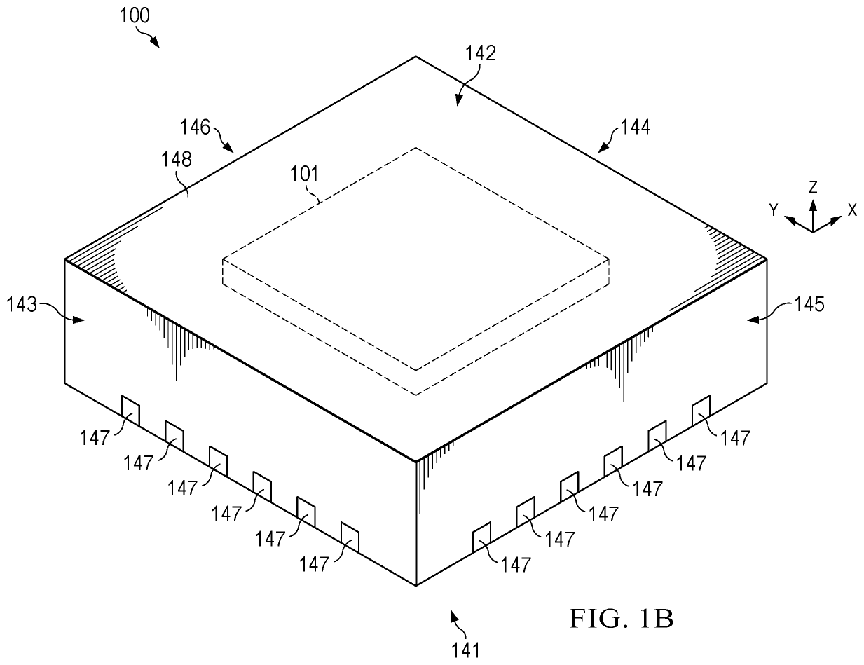

Referring also to FIGS. 2-19, FIG. 2 shows a method 200 for fabricating an electronic device and FIGS. 3-19 show the above described example electronic device 100 undergoing fabrication processing according to the method 200. The method 200 begins at 202 in FIG. 2 with forming an epitaxial layer on a substrate. FIG. 3 shows one example, in which an epitaxial deposition (e.g., growth) process 300 is performed that grows epitaxial layer 104 on a top side of a starting substrate 102 (e.g., during processing of multiple unit or die areas of a starting wafer that includes the substrate 102). The epitaxial deposition process 300 in one example includes provision of process gas that includes p-type dopants (e.g., boron, etc.) to provide a p-type epitaxial layer 104 on the substrate 102.

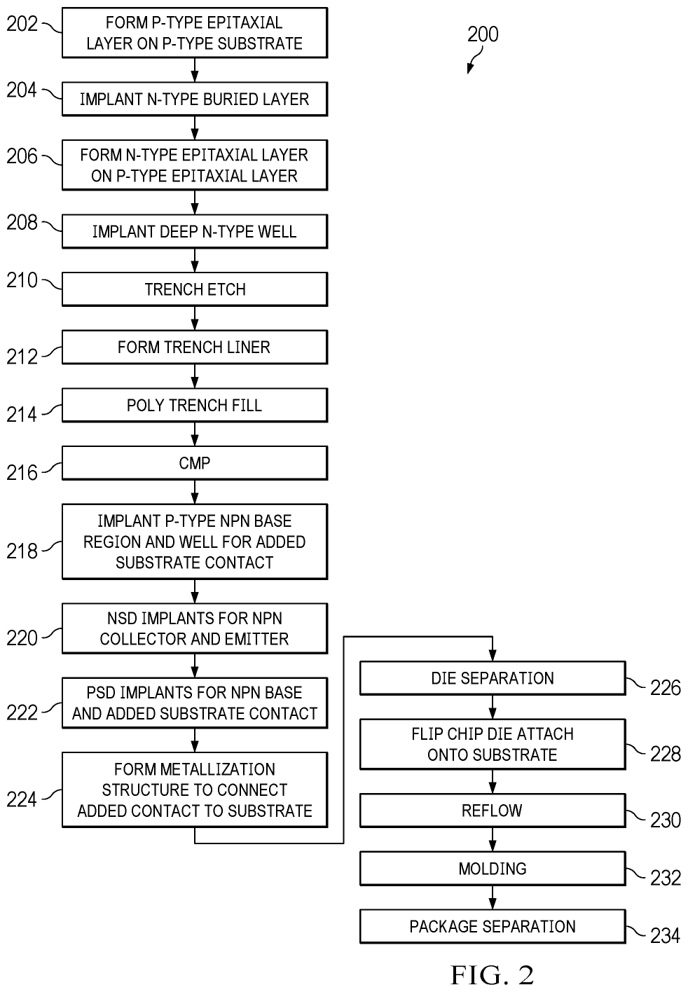

The method 200 continues at 204 in FIG. 2 with implantation of the buried layer 105 and an upper portion of the p-type epitaxial layer 104. FIG. 4 shows one example, in which an implantation process 400 is performed using an implant mask 402. The implantation process 400 implants n-type dopants (e.g., phosphorus, etc.) it to the exposed portions of the top side of the p-type epitaxial semiconductor layer 104 to provide a net n-type doping of the buried layer 105 portion of the epitaxial layer 104, where the buried layer 105 includes majority carriers of the second type (e.g., n-type).

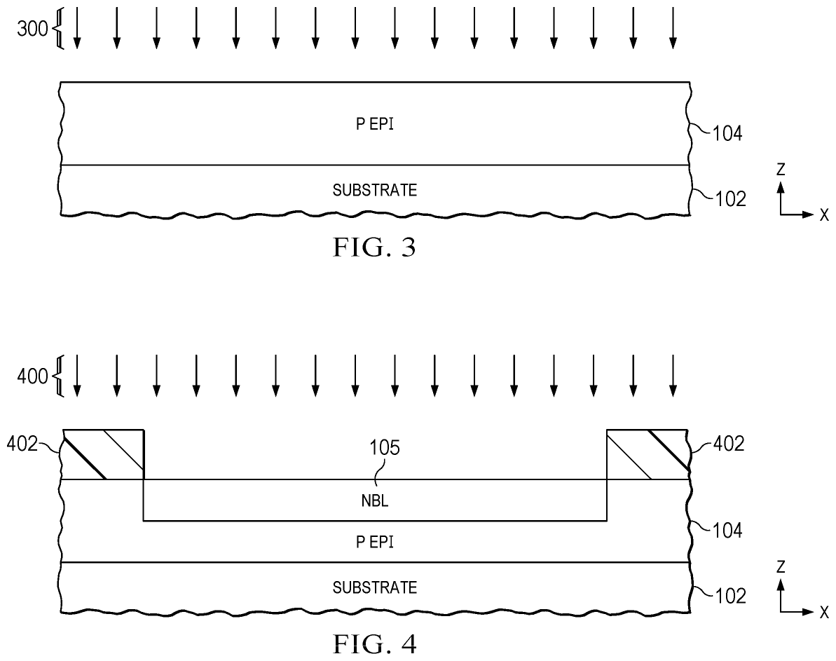

The method 200 continues at 206 in FIG. 2 with forming the n-type epitaxial semiconductor layer 106 on the p-type epitaxial layer 104. FIG. 5 shows one example, in which an epitaxial deposition (e.g., growth) process 500 is performed that deposits (e.g., grows) n-type doped epitaxial silicon to form the epitaxial semiconductor layer 106 on the top side of the p-type epitaxial semiconductor layer 104. The epitaxial deposition process 300 in one example includes provision of process gas that includes n-type dopants (e.g., phosphorus, etc.) to provide the n-type doped first epitaxial silicon layer 106 on the p-doped second epitaxial silicon layer 104. The deposition process 500 in one example cause a slight upward diffusion of previously implanted lower case and-type dopants (e.g., phosphorus) from the buried layer 105, and the dopant diffusion extends the buried layer 105 into a lower portion of the deposited n-type epitaxial semiconductor layer 106 as shown in FIG. 5.

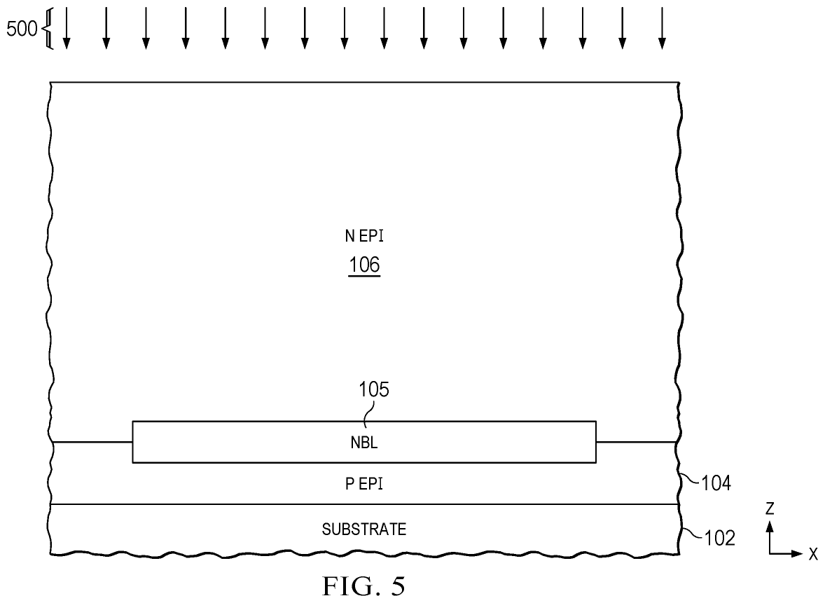

The method 200 continues at 208 in FIG. 2 with implantation of the deep n-well 110 described above in connection with FIGS. 1 and 1A. FIG. 6 shows one example, in which an implantation process 600 is performed with an implant mask 602 that exposes prospective first collector portions of the top surface of the n-type epitaxial semiconductor layer 106 in each unit area or prospective die area of the processed wafer. The implantation process 600 implants n-type dopants to form the deep implanted region 110 as shown in FIG. 6, where the implanted region 110 includes n-type dopants (e.g., phosphorus) with a dopant concentration in one example that is higher than that of the n-type epitaxial semiconductor layer 106.

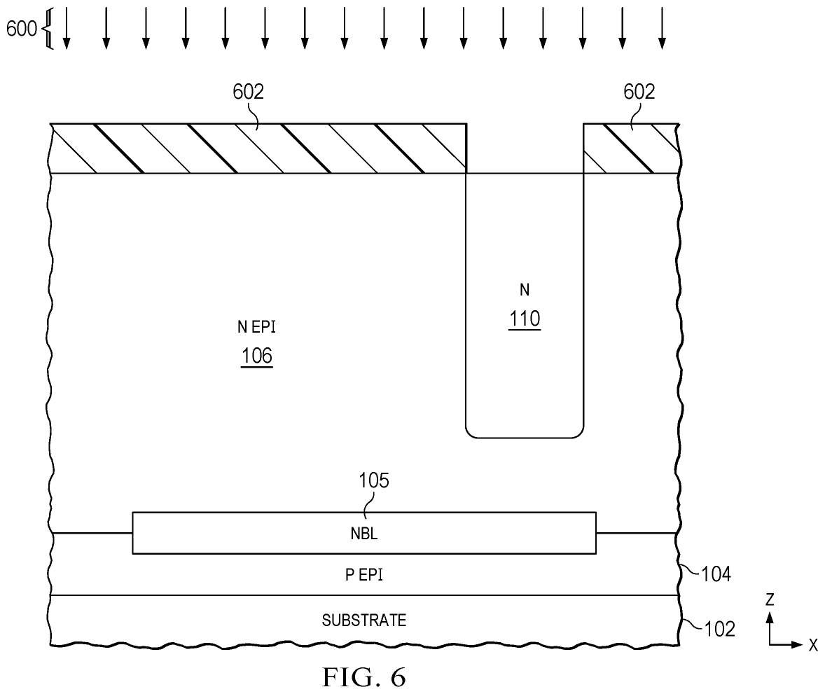

The method 200 continues at 210-216 in FIG. 2 to form the example deep trench isolation structure 107 described above, and thereby define the lateral extent of the isolation tank 103 in FIGS. 1 and 1A above. In another example, different isolation structures (e.g., junction implants, etc.) can be used to define an isolation tank region. The illustrated example begins with trench etching at 210 in FIG. 2. FIG. 7 shows one example, in which an etch process 700 is performed using an etch mask 702 in order to etch trenches that extend through the first (n-type) epitaxial semiconductor layer 106, the second (p-type) epitaxial semiconductor layer 104, and into a portion of the top side of the semiconductor substrate 102 as shown in FIG. 7. As illustrated in FIG. 1 above, moreover, the illustrated example includes a single trench that laterally encircles the prospective isolation tank 103 for each prospective trench isolated NPN transistor Q1 in each unit or die area of the processed wafer.

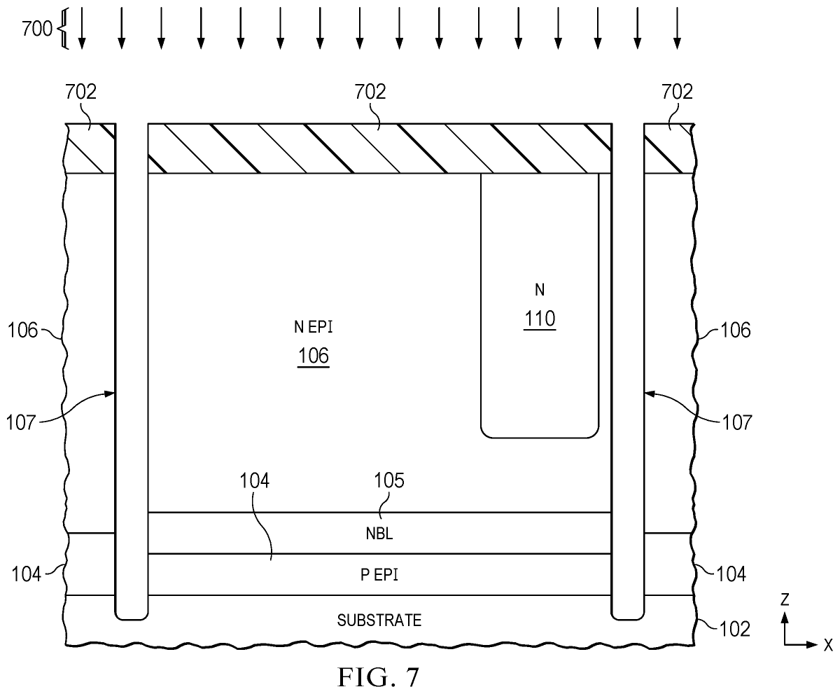

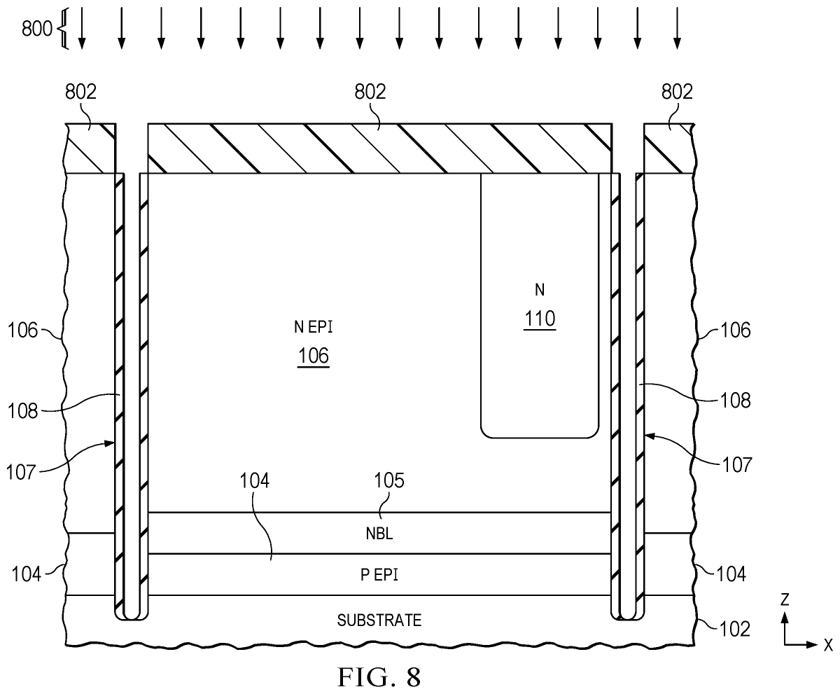

At 212 in FIG. 2, the method 200 continues with trench liner formation. FIG. 8 shows one example, in which an oxidation process 800 is performed which oxidizes the exposed trench sidewalls to form silicon dioxide as the trench liner 108 extending along the sidewalls of the trench. The method 200 continues at 214 in FIG. 2 with polysilicon deposition to fill the trenches. FIG. 9 shows one example, in which a polysilicon deposition process 900 is performed that forms the doped polysilicon 109 on the trench liner 108 in the trench, with the doped polysilicon 109 extending down to form a conductive contact to the exposed portions of the substrate 102 at the bottom of the trench.

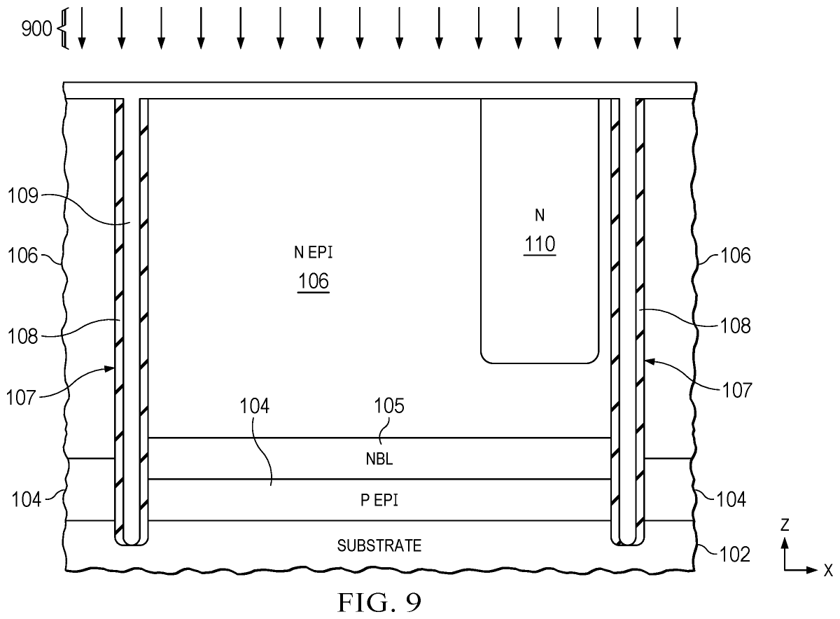

The method 200 continues at 216 in FIG. 2 in one example with planarization to remove any excess polysilicon that extends over the top side of the epitaxial semiconductor layer 106. FIG. 10 shows one example, in which a chemical mechanical polishing (CMP) process 1000 is performed that planarize the top side of the epitaxial semiconductor layer 106. In one example, after the trench isolation at 210-216, shallow trench isolation structures can be formed (not shown), for example between the base region 114 and the n-well 110 and between the base region 114 and the p-well 120.

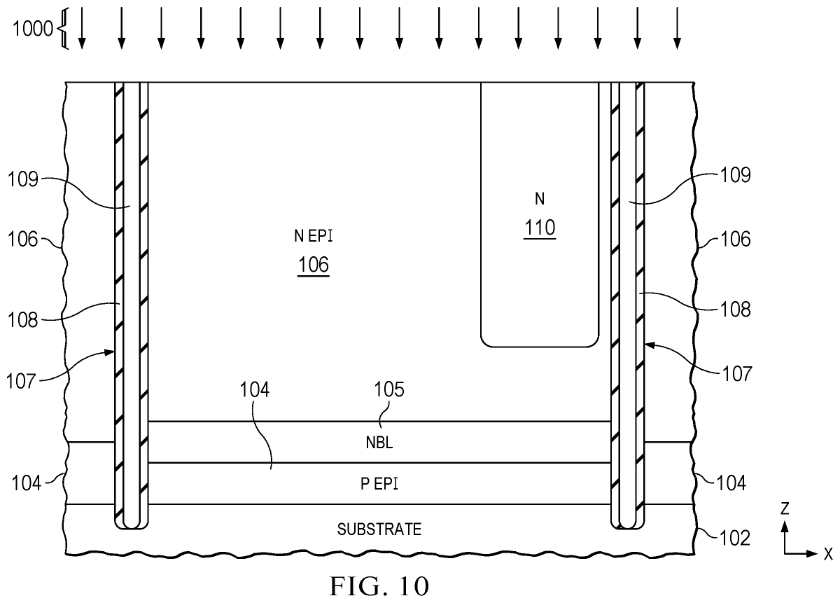

The method 200 continues at 218 in FIG. 2 with implantation of the p-type base region 114 and the p-well 120 of the second collector region. FIG. 11 shows one example, in which an implantation process 1100 is performed with an implant mask 1102 in order to implant p-type dopants (e.g., boron) into exposed portions of the top side or top surface of the epitaxial semiconductor layer 106. The implantation process 1100 in this example concurrently forms the p-type base region 114 and the p-well 120, which in one example can extend to approximately the same depths along the third direction Z within the upper portion of the epitaxial semiconductor layer 106, and which can have the same or similar p-type dopant concentrations. In another implementation, the base region 114 and p-well 120 can be formed by separate processes.

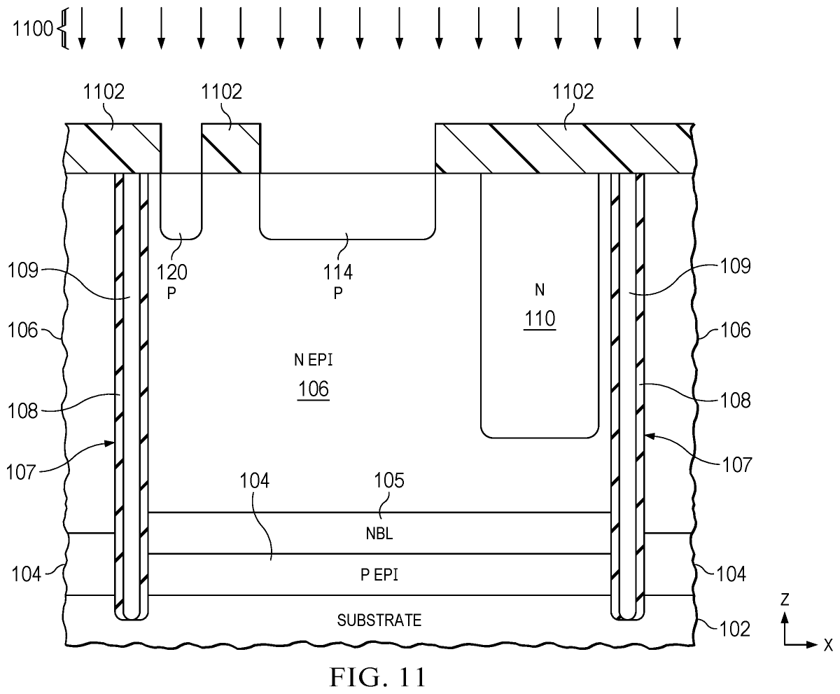

The method 200 continues at 220 in FIG. 2 with n-type source drain implants (NSD implants) to form the NPN transistor collector and emitter. FIG. 12 shows one example, in which an implantation process 1200 is performed using an implant mask 1202 in order to implant n-type dopants (e.g., phosphorus) into the exposed portions of the top surface of the epitaxial semiconductor layer 106. The implantation process 1200 in the illustrated example concurrently implants phosphorus or other n-type dopants into the illustrated openings in the implant mask 1202 in order to concurrently form the N+ implanted regions 112 and 116 of the respective NPN transistor collector C1 and emitter E1. In this example, the implanted regions 112 and 116 extend to approximately the same depths along the third direction Z and have the same or similar n-type dopant concentrations which are higher than the concentration of the implanted region 110. In another implementation, the implanted regions 112 and 116 can be formed by separate processes (not shown). In one implementation, the implantation process 1200 and the mask 1202 can be used to concurrently form n-type implanted source drain regions (not shown) of one or more further transistors (e.g., field effect transistors) in the individual unit areas of the processed wafer.

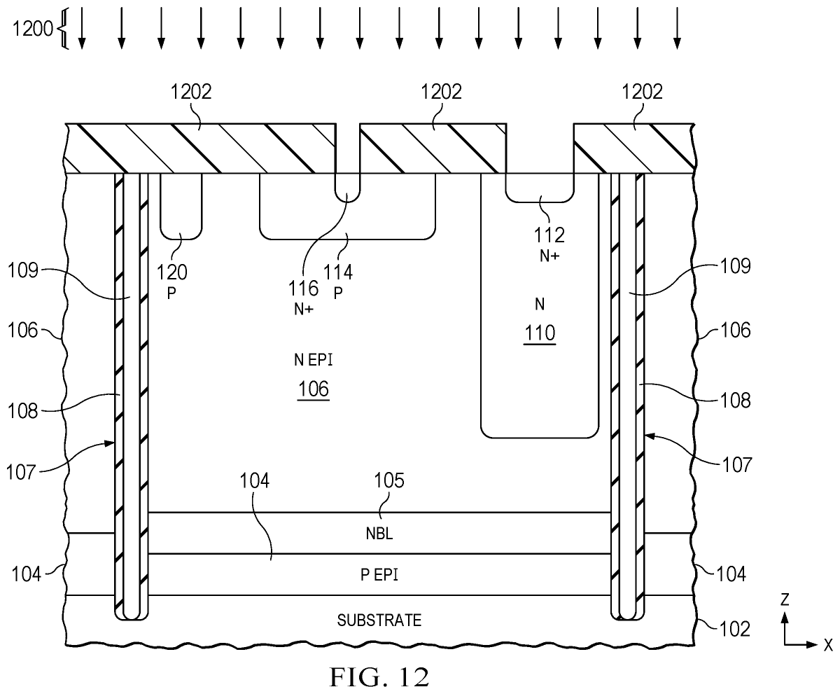

The method 200 continues at 222 in FIG. 2 with p-type source drain implants (PSD implants) to form further portions of the NPN transistor base B1. FIG. 13 shows one example, in which an implantation process 1300 is performed using an implant mask 1302 in order to implant boron or other p-type dopants to form the base contact region 118, the p-type region 122 of the second collector, and the deep-trench contacts 124. The illustrated example concurrently forms the implanted regions 118, 122, and 124 using corresponding openings in the implant mask 1302. In another implementation, separate implantation processes can be used to separately form the implanted regions 118, 122, and 124. In the illustrated example, the implanted regions 118, 122, and 124 extend to approximately the same depth along the third direction Z, and the implanted regions 118, 122, and 124 have approximately the same or similar concentrations of p-type dopants, where the dopant concentrations of the implanted regions 118, 122, and 124 are greater than the corresponding dopant concentrations of the base region 114 and p-well 120 in one example.

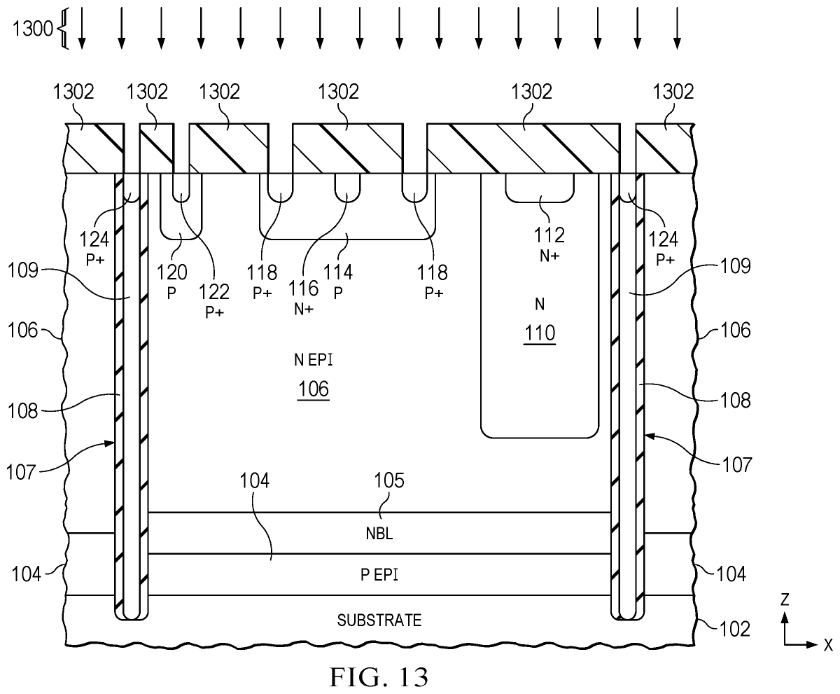

The method 200 continues at 224 in FIG. 2 with metallization processing to form a single or multilevel metallization structure. As previously discussed in connection with FIG. 1A, the illustrated example includes a multilevel metallization structure 130. FIG. 14 shows one example, in which a multistep metallization process 1400 is performed that forms the PMD layer and corresponding tungsten contacts 131 and 132, and then forms the ILD layer and associated conductive metal features (e.g., traces) 134 and any final top level device terminal conductive features. In the illustrated example, the metallization structure provides an electrical connection between the added p-type regions 120, 122 and the conductive polysilicon 109 of the deep trench isolation structure to provide a conductive path between the n-type epitaxial silicon of the semiconductor layer 106 within the isolation tank 103 (FIG. 1A) and the substrate 102.

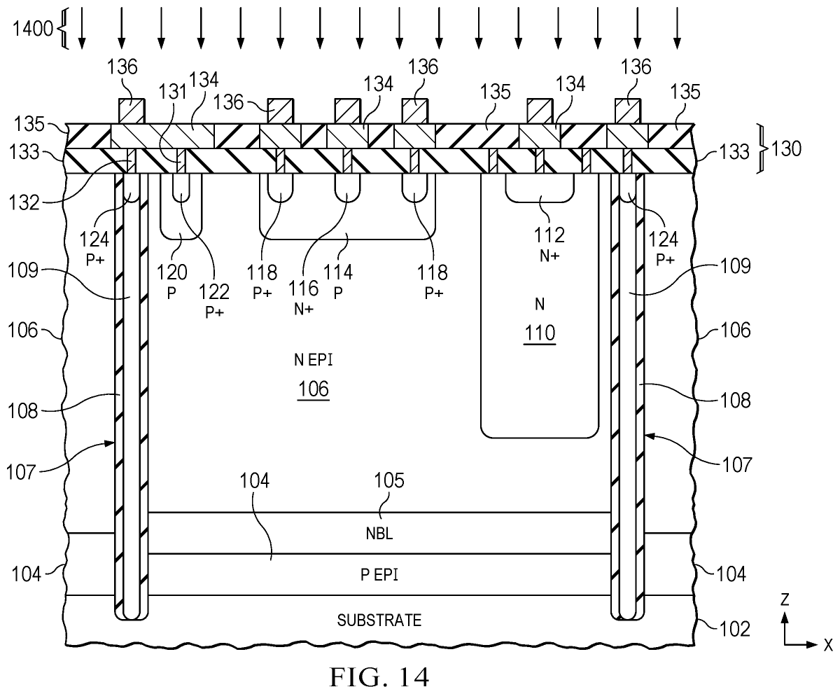

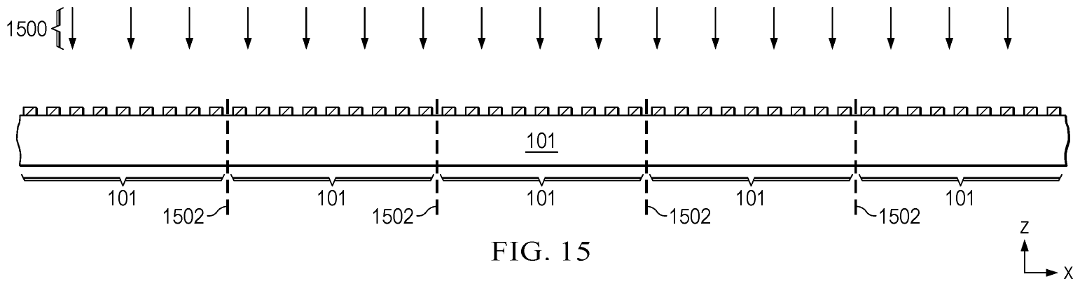

The method 200 continues with die separation and packaging operations at 226 to 234 in FIG. 2. Die separation processing is performed at 226 to separate the individual processed semiconductor dies 101 from the processed substrate 102. FIGS. 15 and 15A show one example, in which individual dies 101 of the wafer are separated from one another along lines 1502 shown in FIG. 15 by a die separation process 1500. In one example, laser dicing is used in which a laser (not shown) is translated along scribe streets between adjacent rows and columns of dies 101 along one side of the wafer (e.g., from the bottom or backside in one example). The laser dicing creates fractures and cracks in the wafer, and the wafer is installed on a carrier or tape structure. The tape is then stretched radially outward by an expansion process 1600 as shown in FIG. 16 to separate individual processed semiconductor dies 101 from one another and from the starting wafer structure.

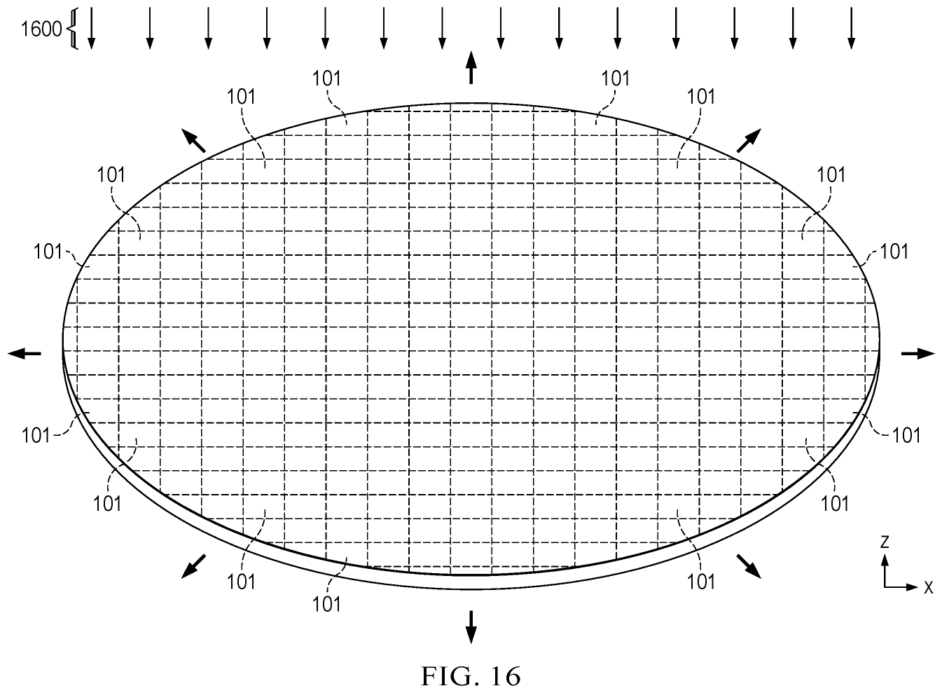

The separated semiconductor dies 101 are then used as components in a packaging operation at 228 to 234 in FIG. 2 in order to create packaged electronic devices 100. In the illustrated example, the semiconductor dies 101 are flip chip attached (e.g., soldered) to a substrate at 228 and 230 in FIG. 2. FIG. 17 shows one example, in which a flip chip die attach process 1700 is performed that attaches the metal posts of the individual semiconductor dies 101 to respective top side conductive metal features on an upper level of a starting multilevel package substrate 170 in the form of a panel array having rows and columns of individual unit areas 1701, or dies. In one example, the die attach process 1700 uses automated pick and place equipment (not shown) that places individual semiconductor dies 101 in the corresponding unit areas 1701 of the panel array.

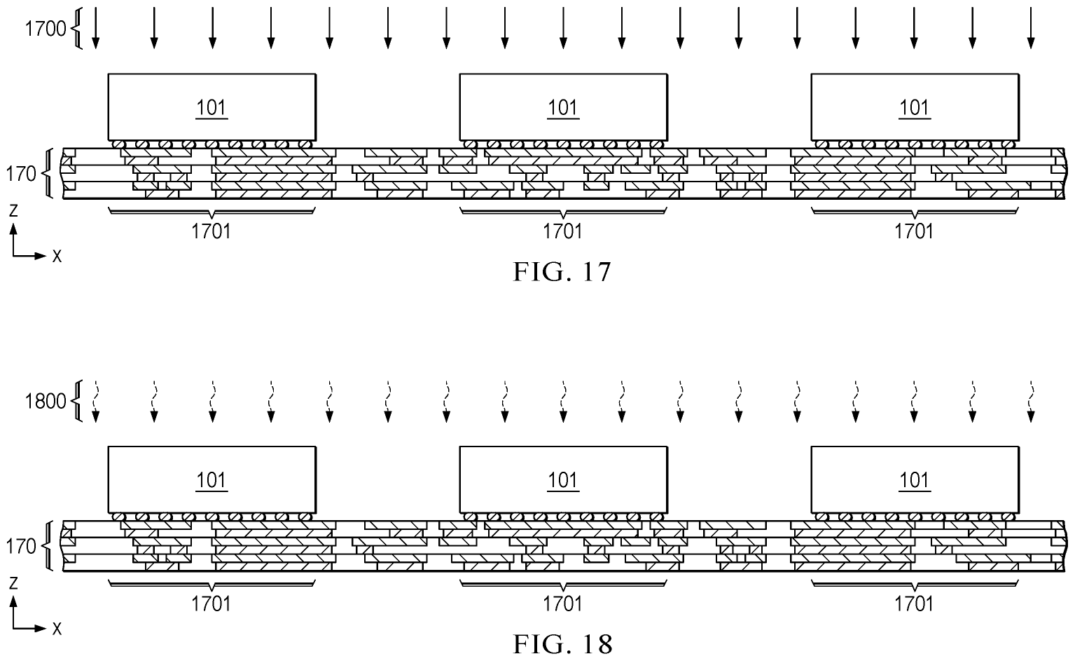

The method 200 continues at 230 in FIG. 2 with reflowing the solder to form solder connections between the die terminals and the associated conductive features along the top side of the multilevel package substrate 170 in each unit area 1701 of the panel array structure. FIG. 18 shows one example, in which a thermal reflow process 1800 is performed that reflows the solder at a suitable temperature for an adequate amount of time to create solder joints that electrically and mechanically interconnect the semiconductor dies 101 with the corresponding unit areas 1701 of the multilevel package substrate 170.

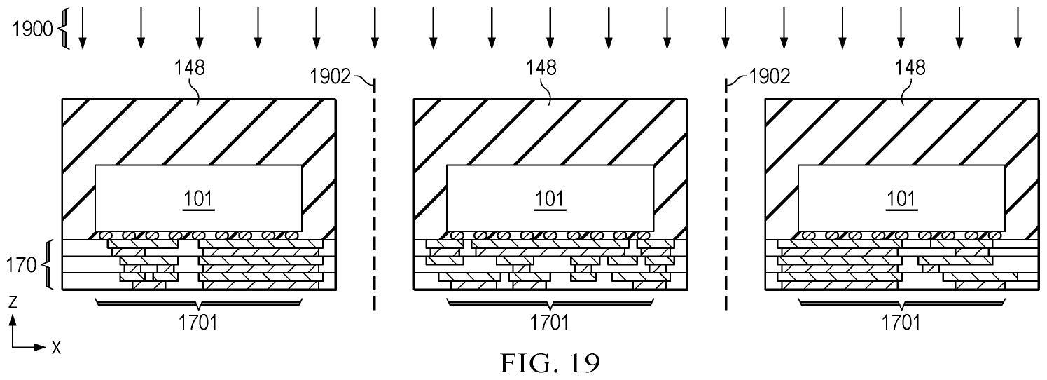

At 232 in FIG. 2, the method 200 continues with molding processing, for example, to form a molded package structure 148 that encloses the semiconductor dies 101 and extends to the exposed top side of the multilevel package substrate 170. In one implementation, a single mold cavity can be used to create a unitary molded structure 148 in all the unit areas 1701 of the panel array structure prior to package separation. In another implementation (not shown), multiple cavities can be used, each including one or more of the unit areas 1701. At 234 in FIG. 2, the method 200 includes package separation processing to separate individual packaged electronic devices 100 from the panel array structure. FIG. 19 shows one example, in which a die separation process 1900 is performed that separates individual packaged electronic devices along lines 1902 between adjacent unit areas 1701. In one example, the die separation process 1900 includes cutting operations using any suitable techniques and equipment (not shown), such as saw cutting, laser cutting, etching, etc. to produce multiple instances of the packaged electronic device 100 illustrated and described above in connection with FIGS. 1-1B.

FIG. 20 shows a partial top view of another example electronic device 2000 including a trench isolated NPN transistor Q1 formed in an isolation tank 103 encircled by a deep trench isolation structure 107 with various similarly numbered structures and features as described above. In this example, the second collector region includes implanted p-type regions 2020 and 2222 analogous to the p-type regions 120, 122, extending generally in the second direction Y, e.g., similar to the p-type regions 120, 122 along a first side of the isolation tank 103. First additional p-type regions 2031 extend from the p-type regions 2020 and 2222 in the first direction X along a second side of the isolation tank 103. Second additional p-type regions 2032 extend from the p-type regions 2020 and 2222 in the first direction X along a third side of the isolation tank 103. In the illustrated example, the p-type regions 2020, 2022 extend along the top surface of the semiconductor layer 106 parallel to three sides of the base region 114 and base contact 118 as shown in FIG. 20, forming a C-shaped structure to enhance the surface area available for hole extraction and reduce the impedance between the n-type epitaxial layer material 106 within the isolation tank 103 and the substrate to facilitate fast reverse bias recovery of the transistor Q1. In this case, the electronic device 100 also includes corresponding contacts and the metallization feature 134 also extends in a substantially C-shaped structure for the above-described reverse recovery transistor performance benefits.

FIG. 21 shows another non-limiting example of an electronic device 2100 that includes a trench isolated NPN transistor Q1 formed in an isolation tank 103 encircled by a deep trench isolation structure 107 with various similarly numbered structures and features as described above. In this example, the transistor Q1 has multiple instances of the emitter region 116, for example, formed in a stack of for such regions along the second direction Y, each including n-type dopants and extending from the top surface of the semiconductor layer 106 into the base region 114 and base contact 118. In this example, moreover, the electronic device 2100 includes a bilaterally symmetrical arrangement with first and second instances of the p-type regions 120 and 122 spaced apart from one another along the first direction X in the isolation tank 103 of the semiconductor layer 106. In addition, the electronic device 2100 in this example includes first and second instances of the n-well 110 that are spaced apart from one another along the second direction Y in the isolation tank 103 of the semiconductor layer 106.

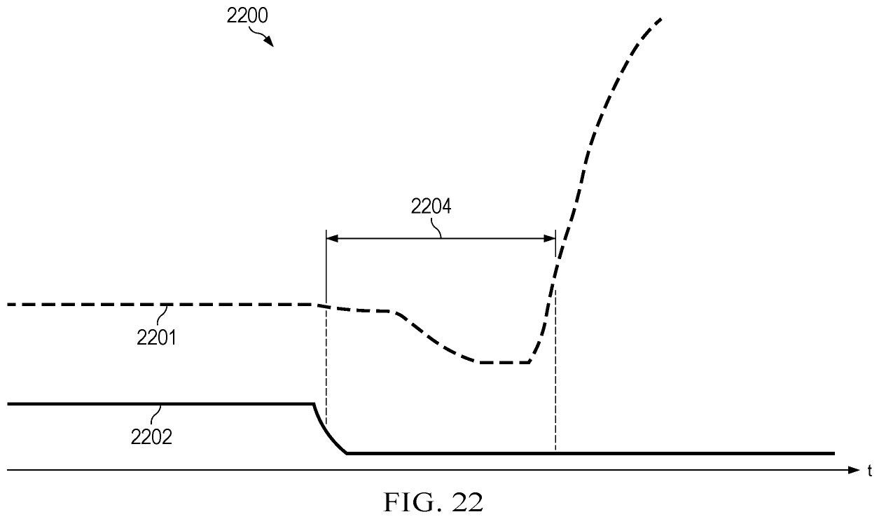

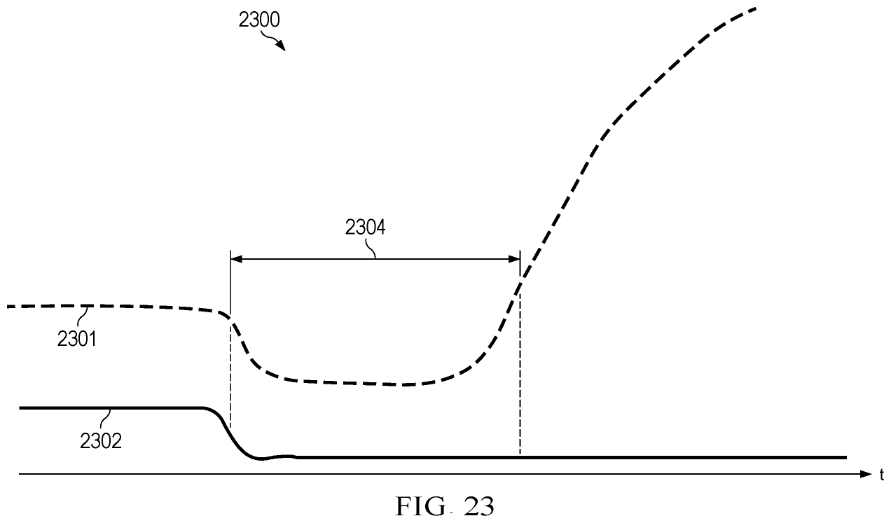

Referring also to FIGS. 22-23, comparative performance graphs are provided to illustrate improved reverse recovery performance benefits that can be achieved using the above-described techniques and structures. These performance graphs are qualitatively representative, and have vertical and horizontal axes that may not be drawn to the same scale. FIG. 22 shows a graph 2200 with a first curve 2201 corresponding to collector-emitter voltage of a baseline NPN transistor, e.g. analogous to the electronic device 100 without the p-type regions 120 and 122, and a second curve 2202 corresponding to an input to a reference resistor connected to the base of the baseline NPN transistor being switched from a starting level to approximately zero in order to turn the transistor off. A reverse recovery time 2204 results between the falling edge of the control signal (curve 2202) and the time at which the collector voltage (curve 2201) reaches a recovery threshold level.

FIG. 23 shows a graph 2300 with a curve 2302 corresponding to the collector voltage of an example device consistent with the above-described NPN transistor Q1 in the isolation tank 103 shown in FIGS. 1 and 1A. A curve 2301 again represents the voltage at an input to a reference resistor connected to the base of the transistor Q1. A resulting recovery time 2304 from the falling edge of the curve 2302 to the recovery threshold value of the curve 2304 is about 60% of the recovery time 2204, accounting for difference of scaling of the horizontal axis. The reduced recovery time is indicative of the benefit of providing the second collector region including the p-type regions 120 and 122, as well as the connection through the metallization structure 130 to the substrate 102 (or other low potential node of the electronic device 100) to extract hole carriers from the isolation tank 103 to significantly reduce the reverse recovery time.

Modifications are possible in the described embodiments, and other embodiments are possible, within the scope of the claims.

The following is claimed:

1. An electronic device, comprising:
a semiconductor layer over a substrate, having a top surface extending in a plane of orthogonal first and second directions and including an isolation tank region extending from the top surface into the semiconductor layer;
a base region having a first conductivity type, the base region extending from the top surface into the isolation tank region, and the semiconductor layer having an opposite second conductivity type;
an emitter region having the second conductivity type, the emitter region extending from the top surface into the base region;
a first collector region having the second conductivity type, the first collector region extending from the top surface into the isolation tank region and spaced apart from the base region; and
a second collector region having the first conductivity type, the second collector region extending from the top surface into the isolation tank region, the second collector region spaced apart from the base region and from the first collector region.

2. The electronic device of claim 1, wherein the second collector region is conductively connected to the substrate.

3. The electronic device of claim 1, further comprising:
a deep trench isolation structure that extends from the top surface through the semiconductor layer to the substrate underlying the deep trench isolation structure laterally surrounding the isolation tank region of the semiconductor layer; and
a metallization structure including metal interconnects that electrically connect the second collector region to the substrate through the deep trench isolation structure.

4. The electronic device of claim 3, wherein the deep trench isolation structure includes: a trench with a sidewall liner and doped polysilicon on the sidewall liner and extending from the top surface to the substrate.

5. The electronic device of claim 3, further comprising a buried layer having the second conductivity type between the semiconductor layer and the substrate and laterally bounded by the deep trench isolation structure.

6. The electronic device of claim 5, comprising a second semiconductor layer having the first conductivity type and extending along a third direction between the semiconductor layer and the semiconductor substrate.

7. The electronic device of claim 1, further comprising a buried layer having the second conductivity type between the semiconductor layer and the substrate and laterally bounded by an isolation structure that surrounds the isolation tank region.

8. The electronic device of claim 1, wherein the second collector region extends along the top surface parallel to two sides of the base region.

9. The electronic device of claim 8, wherein the second collector region extends along the top surface parallel to three sides of the base region.

10. The electronic device of claim 9, wherein the emitter region includes multiple adjacent emitter region instances having the second conductivity type and extending from the top surface into the base region.

11. The electronic device of claim 1, comprising:
first and second instances of the second collector region spaced apart from one another along the first direction in the isolation tank region of the semiconductor layer; and
first and second instances of the first collector region spaced apart from one another along the second direction in the isolation tank region of the semiconductor layer.

12. The electronic device of claim 11, wherein the emitter region includes multiple adjacent emitter region instances having the second conductivity type and extending from the top surface into the base region.

13. The electronic device of claim 1, wherein the first conductivity type is p-type and the second conductivity type is n-type.

14. The electronic device of claim 1, wherein the emitter region includes multiple adjacent emitter region instances having the second conductivity type and extending from the top surface into the base region.

15. An integrated circuit, comprising:
an epitaxial layer over a semiconductor substrate;
an isolation structure surrounding an isolation tank region and including a portion of the epitaxial layer;
a base well having a first conductivity type and extending into the isolation tank region, the epitaxial layer having an opposite second conductivity type;
a transistor terminal having the second conductivity type and extending into the base well;
a first well having the second conductivity type and extending into the isolation tank region and spaced apart from the base well; and
a second well having the first conductivity type and extending into the isolation tank region and spaced apart from the base well,
wherein:
the transistor terminal, the base well, the isolation tank region, and the first well form a first bipolar transistor having a first polarity type, and
the base well, the isolation tank region, and the second well form a second bipolar transistor having a second polarity type.

16. A method of fabricating an electronic device, the method comprising:
forming a base region having a first conductivity type in an isolation tank region of a semiconductor layer over a substrate that supports the semiconductor layer, the semiconductor layer having a second conductivity type;
forming an emitter region having the second conductivity type in the base region;
forming a first collector region having the second conductivity type in the isolation tank region and spaced apart from the base region; and
forming a second collector region having the first conductivity type in the isolation tank region and spaced apart from the base region and from the first collector region.

17. The method of claim 16, further comprising forming an isolation structure laterally surrounding the isolation tank region and contacting the substrate.

18. The method of claim 16, further comprising forming a metallization structure that conductively connects the second collector region to the substrate by way of a deep trench isolation structure.

19. The method of claim 18, further comprising forming a buried layer having the second conductivity type between the semiconductor layer and the substrate.

20. The method of claim 16, wherein the second collector region extends parallel to two sides of the base region along a top surface of the semiconductor layer.
